(19) United States
(12) Patent Application Publication
(10) Pub. No.: US 2005/0051893 A1
(43) Pub. Date: Mar. 10, 2005

(54) SBGA design for low-k integrated circuits (IC)

(75) Inventors: Yian-Liang Kuo, Hsinchu City (TW); Yung-Sheng Huang, Hsin-Chu (TW); Yu-Ting Lin, Hsin-Chu (TW)

Correspondence Address: GEORGE O. SAILE, 28 DAVIS AVENUE, POUGHKEEOSIE, NY, 12603, US

(73) Assignee: Taiwan Semiconductor Manufacturing Co.

(21) Appl. No.: 10/655,689

(22) Filed: Sep. 5, 2003

(51) Int. Cl. H01L 23/48

(52) U.S. Cl. 257/734

(57) ABSTRACT

A method of forming a ball grid array package, and the resultant ball grid array package, comprising the following steps. A semiconductor chip/die is provided. A ball grid substrate having: a heat spreader with a pattern of slots formed therein; and a series of balls is provided. The semiconductor chip/die is affixed to the ball grid substrate.

### FIELD OF THE INVENTION

The present invention relates generally to semiconductor chip packaging and more specifically to ball grid array (BGA) packages.

### BACKGROUND OF THE INVENTION

Due to concerns about thermal effectiveness, high input-output (IO) number and high speed, super ball grid array (SBGA) packages are selected for some products which have very large power consumption. Super BGA is cavity down (die down), thermally enhanced BGA. It is also called L2BGA (Laser Laminated BGA), EBGA (Enhanced BGA), TBGA (Tape BGA), etc.

The low dielectric constant (k) (LK) dies in SBGA were attached to heat spreaders having a larger coefficient of expansion (CTE) than silicon, i.e. the silicon semiconductor chips. This causes failure of TC/TS tests due to the large mismatch between the CTE of the heat spreaders used and the CTE of the silicon semiconductor chips. LK (low-k) is a dielectric material having a dielectric constant of less than about 3.9, the dielectric constant of silicon oxide (SiO₂), that is used to insulate adjacent metal lines (interlayer dielectric (ILD)) in advanced micro devices. Low-k material reduces capacitive coupling (“cross-talk”) between lines. LK dies are dies with LK IMD (intermetal dielectric) layers, i.e. their IMD layers use LK dielectric materials.

TC is Temperature Cycling and a TC test is conducted to determine the resistance of a part to extremes of high and low temperatures, and to alternate exposures to these extremes. TS is Thermal Shock and the purpose of TS testing is to determine the ability of sold state devices to withstand exposure to extreme changes in temperature by thermally stressing the device. Thermal shock effects include cracking and delamination of substrates or wafers, opening of terminal seals or case seams and changes in electrical characteristics. If more than 30 cycles are performed, the test is considered to be destructive.

U.S. Pat. No. 5,977,633 to Suzuki et al. describes a semiconductor device with metal base substrate having hollows.

U.S. Pat. No. 5,223,741 to Bechtel et al. describes a package for an integrated circuit structure.

U.S. Pat. No. 5,585,671 to Nagesh et al. describes a low thermal resistance package for high power flip chip ICS.

U.S. Pat. No. 6,462,410 B1 to Novotny et al. describes an integrated circuit component temperature gradient reducer.

U.S. Pat. No. 4,748,495 to Kucharek describes a high density multi-chip interconnection and cooling package.

### SUMMARY OF THE INVENTION

Accordingly, it is an object of one or more embodiments of the present invention to provide an improved super ball grid array (SBGA) design and a method of fabricating the same.

Another object of the present invention is to apply the inventive concept of the present invention at traditional HSBGA (PBGA with a heat spreader) and HSFCBGA (a flip chip BGA with a heat spreader).

Other objects will appear hereinafter.

It has now been discovered that the above and other objects of the present invention may be accomplished in the following manner. Specifically, semiconductor chip/die is provided. A ball grid substrate having: a heat spreader with a pattern of slots formed therein; and a series of balls is provided. The semiconductor chip/die is affixed to the ball grid substrate. The invention also includes the ball grid array package structure so formed.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 and 2 schematically illustrate a preferred embodiment of the present invention with FIG. 2 being a cross-sectional view of FIG. 1 along line 2-2.

FIGS. 3A to 3G, respectively, schematically illustrate other permissible examples of slot patterns.

### DETAILED DESCRIPTION OF THE PREFERRED EMBODIMENT

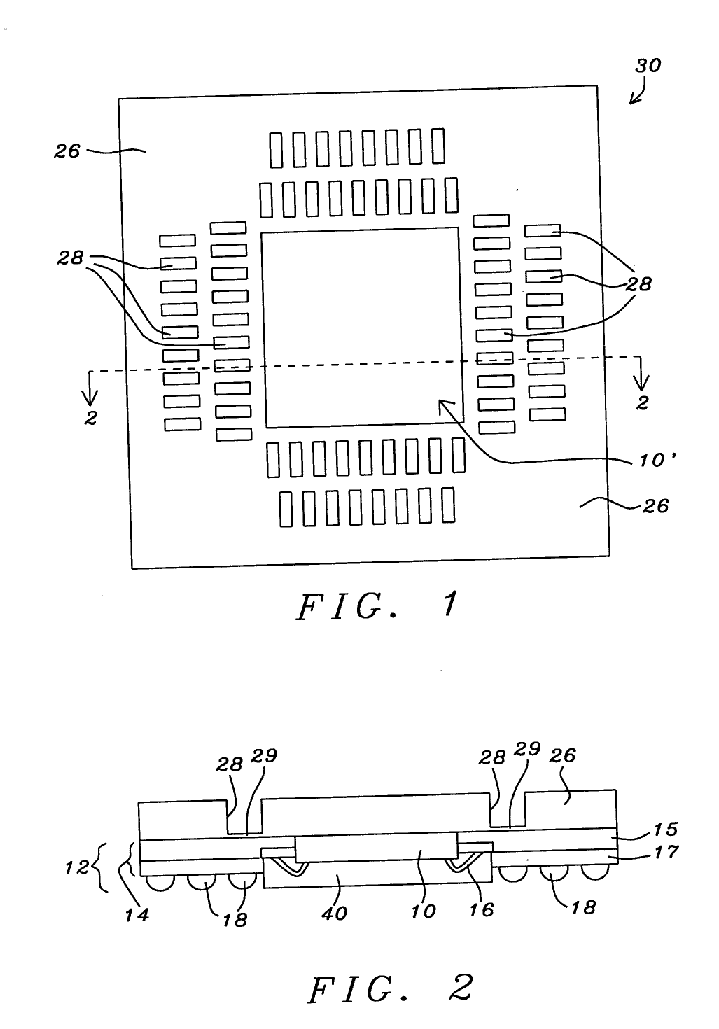

Top Down Plan View—FIG. 1

FIG. 1 illustrates a top-down plan view of the super BGA package 30 of the preferred embodiment of the present invention showing the slots 28 formed within the heat spreader/substrate 26 centered over the semiconductor chip/die 10 represented by area 10′. Slots 28 do not completely pierce heat spreader 26 so as to prevent deleterious effects of moisture, for example, on the underlying super ball grid array (SBGA) chip 12. Semiconductor chip/die 10 is preferably comprised of silicon (Si) or germanium (Ge) and is preferably silicon as will be used for purposes of illustration hereafter.

It is noted that while an SBGA chip is illustrated in the Figs., the concepts of the present invention may also be applied to traditional HSBGA and HSFCBGA chips.

Heat spreader 26 is preferably comprised of copper (Cu), aluminum (Al), chromium (Cr) plated on Cu or Al or nickel (Ni) plated on Cu or Al and is more preferably Ni plated on Cu. The coefficient of thermal expansion (CTE) of the heat spreader 26 is preferably from about 10 to 25 depending upon the materials and is more preferably about 17 for copper (Cu).

Slots 28 are arranged in a pattern around, but not over, silicon semiconductor chip/die 10 (area 10′ in FIG. 1). The number or density of slots 28 are determined by a simulation of finite analysis that balances stress-reduction, heat-release and mechanically-robust performance and depends upon the die size, produced heat and environmental conditions.

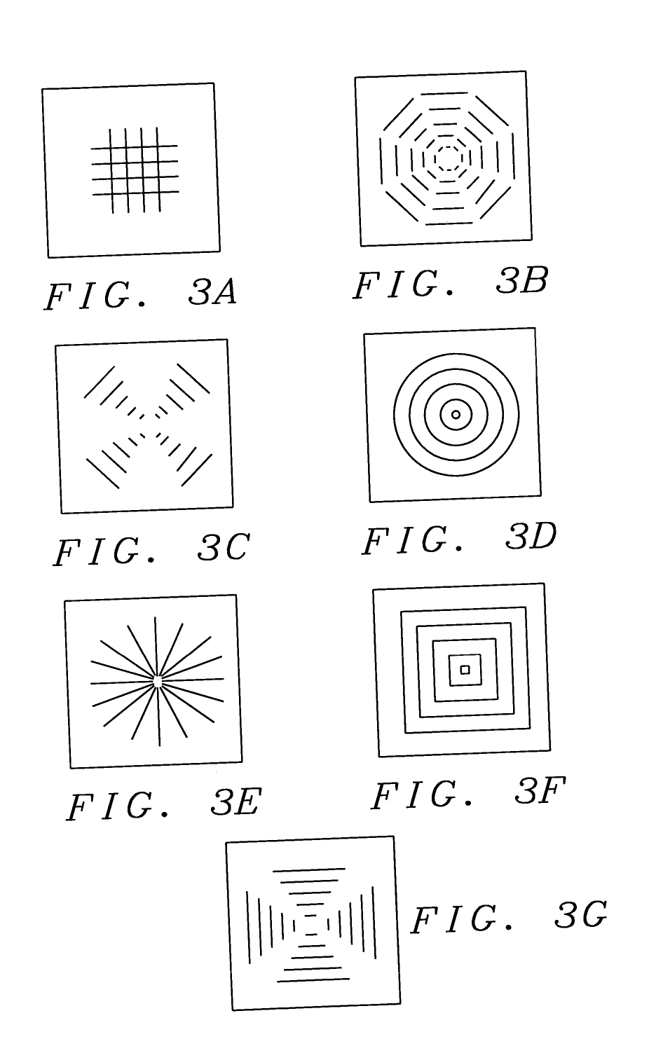

The patterns for slots 28 may be that shown in FIG. 1, i.e. parallel/perpendicular rows, or, for further examples, those shown in FIGS. 3a to 3g such as, for example, circular, radiated, rectangular, square, concentric circular, concentric square, concentric octagonal etc.

Individual slots 28 may be rectangular as shown in FIGS. 1 and 2, square, triangular, circular, polygonal, etc. and are more preferably rectangular.

When in the pattern specifically shown in FIG. 1, slots 28 within a row facing area 10′ are preferably spaced apart from each other by from about 0.5 to 2.5 mm and more preferably from about 0.7 to 1.5 mm and the rows are spaced apart from each other by from about 1.0 to 5.0 mm and more preferably from about 1.5 to 2.5 mm.

Cross-Sectional View—FIG. 2

FIG. 2 illustrates a cross-sectional view of FIG. 1 along line 2-2 showing heat spreader 26 mounted over super ball grid array (SBGA) chip 12 with slots 28 outboard of the silicon semiconductor chip/die 10.

The remaining thickness of heat spreader 26 at slots 28 as at 29 is preferably from about 15 to 75% of the thickness of the heat spreader 26 and more preferably from about 25 to 50% of the thickness of the heat spreader 26. Thus, slots 28 penetrate the heat spreader 26 by preferably from about 85 to 25% and more preferably from about 75 to 50%.

The slots 28 may be set on the die area.

The super ball grid array (SBGA) chip 12 includes silicon semiconductor chip 10 mounted onto a substrate 14 and is electrically connected to substrate 14 by, for example, lead wire structures 16.

Substrate 14 has an upper layer 15 and a lower layer 17. Upper layer 15 is preferably from about 0.3 to 1.75 mm thick and is more preferably from about 1.0 to 1.5 mm thick and is preferably comprised of a copper (Cu) ring (for 2 laminated structure which is most used) or polyimide dielectric, polymer, Cu (metal trace), resin, etc. and more preferably a copper ring (for 2 laminated structure). Lower layer 17 is preferably from about 0.2 to 1.5 mm thick and is more preferably from about 0.3 to 1.0 mm thick and is preferably comprised of polyimide dielectric, polymer, Cu (metal trace), resin, solder resist, etc.

Substrate 14 includes balls 18 mounted on its surface opposite the heat spreader 26. Balls 18 are preferably comprised of 63Sn37Pb (63% Sn+37% Pb—likely to be forbidden due to environmental protection), 96.5Sn3.5Ag (96.5% Sn+3.5% Ag—lead-free and expected to be used in the future due to environmental protection), 95.5Sn3.8Ag0.7Cu (95.5% Sn+3.8% Ag+0.7% Cu—lead-free) or 96.2Sn2.5Ag0.8Cu0.5Sb (96.2% Sn+2.5% Ag+0.8% Cu+0.5% Sb—lead-free) and are more preferably 63Sn37Pb for the present and 96.5Sn3.5Ag if 63Sn37Pb is banned.

Encapsulate 40 encapsulates the otherwise exposed silicon semiconductor chip/die 10 and lead wire structures 16 and protects it from moisture and chemical and physical insult. Encapsulate 40 is preferably comprised of epoxy resin, filler, curing agent, etc.

Semiconductor chip/die 10 generally has a coefficient of thermal expansion (CTE) of preferably from about 2.5 to 3.5 and more preferably about 2.8 when comprised of silicon and from about 5.5 to 6.5 and more preferably about 6.1 when comprised of germanium and heat spreader 26 generally has a CTE of preferably from about 10 to 25 and more preferably about 17 for copper (Cu) depending upon the materials. This juxtaposition of materials having such dissimilar CTEs is mitigated by the use of slots 28 within heat spreader 26 which serve to release accumulated thermal expansion stress and thus reduce the impact upon the underlying (silicon) semiconductor chip/die 10 and the SBGA chip 12. The three-dimensional nature of slots 28 improves the thermal effectiveness of the heat spreader 26 with lower stress impact on LK semiconductor chips/dies 10.

The instant invention applies slots 28 on the metal substrate/heat spreader 26 to reduce expansion stress impact of the metal substrate/heat spreader 26 on the low-k die/semiconductor chip 10. As noted above, varying slot types and slot patterns/distributions are acceptable. This concept may be applied not only to SBGA's but also with other packages with heat spreaders such as HSFCBGA's and HSBGA's which are hard to assemble LK dies.

Advantages of the Present Invention

The advantages of one or more embodiments of the present invention include:
1. realize SBGA package types on LK dies;
2. enhance heat-releasing performance;
3. no extra assembly process or tools are needed; and
4. the same slot concept can be applied on the heat spreader of other packages.

While particular embodiments of the present invention have been illustrated and described, it is not intended to limit the invention, except as defined by the following claims.

1-37. Canceled.

38. An ball grid array package, comprising:
a semiconductor chip/die affixed to a ball grid substrate; the ball grid substrate having a series of balls; and
a heat spreader mounted to the semiconductor chip/die and the ball grid substrate opposite the series of balls; the heat spreader having a pattern of slots therein.

39. The structure of claim 38, wherein the semiconductor chip is a silicon semiconductor chip or a germanium semiconductor chip.

40. The structure of claim 38, wherein the semiconductor chip is a silicon semiconductor chip.

41. The structure of claim 38, wherein the balls are comprised of 63Sn37Pb, 96.5Sn3.5Ag, 5.5Sn3.8Ag0.7Cu or 96.2Sn2.5Ag0.8Cu0.5Sb; and the heat spreader is comprised of copper, aluminum, chromium plated on copper, chromium plated on aluminum or nickel plated on copper.

42. The structure of claim 38, wherein the balls are comprised of 63Sn37Pb or 96.5Sn3.5Ag; and the heat spreader is comprised of nickel plated on copper.

43. The structure of claim 38, wherein the balls are comprised of 63Sn37Pb.

44. The structure of claim 38, wherein the balls are comprised of 96.5Sn3.5Ag.

45. The structure of claim 38, wherein the semiconductor chip/die is a silicon semiconductor chip/die and has a coefficient of thermal expansion of from about 2.5 to 3.5; and the heat spreader has a coefficient of thermal expansion of from about 10 to 25.

46. The structure of claim 38, wherein the semiconductor chip/die is a silicon semiconductor chip/die and has a coefficient of thermal expansion of about 2.8; and the heat spreader has a coefficient of thermal expansion of about 17.0.

47. The structure of claim 38, wherein the semiconductor chip/die is a germanium semiconductor chip/die and has a coefficient of thermal expansion of from about 5.5 to 6.5; and the heat spreader has a coefficient of thermal expansion of about 10 to 25.

48. The structure of claim 38, wherein the semiconductor chip/die is a germanium semiconductor chip/die and has a coefficient of thermal expansion of about 6.1; and the heat spreader has a coefficient of thermal expansion of about 17.0.

49. The structure of claim 38, wherein the slots penetrate the heat spreader from about 25 and 85%.

50. The structure of claim 38, wherein the slots penetrate the heat spreader from about 50 to 75%.

51. The structure of claim 38, wherein the pattern of slots include rows spaced apart from about 1.0 and 5.0 mm; the slots 28 comprising each row are spaced apart from each other from about 0.5 to 2.5 mm.

52. The structure of claim 38, wherein the pattern of slots include rows spaced apart from about 1.5 to 2.5 mm; the slots comprising each row are spaced apart from each other from about 0.7 and 1.5 mm.

53. The structure of claim 38, wherein the pattern of slots 28 are arranged in: perpendicular/perpendicular rows; a circular pattern; a radiating pattern; a rectangular pattern, a square pattern, a concentric circular pattern, a concentric square pattern, or a concentric octagonal pattern.

54. The structure of claim 38, wherein the pattern of slots 28 are arranged in: parallel/perpendicular rows.

55. The structure of claim 38, wherein the ball grid array package is a super ball grid array package, an HSBGA package or an HSFCBGA.

56. The structure of claim 38, wherein the ball grid array package is a super ball grid array package.
